(19) United States
(12) Patent Application Publication
(10) Pub. No.: US 2009/0109218 A1
(43) Pub. Date: Apr. 30, 2009

(54) SYSTEM FOR SUPPORTING RECOGNITION OF AN OBJECT DRAWN IN AN IMAGE

(75) Inventors: Akira Koseki, Sagamihara-shi (JP); Shuichi Shimizu, Yokohama-shi (JP)

Correspondence Address: Anne Vachon Dougherty, 3173 Cedar Road, Yorktown Hts, NY, 10598, US

(73) Assignee: International Business Machines Corporation, Armonk, NY (US)

(21) Appl. No.: 12/208,751

(22) Filed: Sep. 11, 2008

(30) Foreign Application Priority Data
Sep. 13, 2007 (JP) 2007-237839

(51) Int. Cl. G06T 15/40; G09G 5/00; H03G 3/20; G06T 15/00

(52) U.S. Cl. 345/422; 345/156; 345/419; 381/107

(57) ABSTRACT

A system including a memory device that stores, in association with each of a plurality of areas obtained by dividing an input image, an feature amount of an object drawn in the area; a selection section that selects a range of the input image to be recognized by a user based on an instruction therefrom; a calculation section that reads the feature amount corresponding to each area contained in the selected range from the memory device, and calculates an index value based on each read feature amount; and a control section that controls a device which acts on an acoustic sense or a touch sense based on the calculated index value.

### FIELD OF THE INVENTION

The present invention relates to a system that supports a user's recognition of an object. Particularly, the present invention relates to a system that supports recognition of an object by using a device which acts on an acoustic sense or a touch sense of a user.

### BACKGROUND OF THE INVENTION

There is increasingly widespread implementation of systems that permit a user to experience a virtual three-dimensional world by using a computer. As a result, it becomes expected that the virtual world systems explore their business usage such as providing virtually created services which have been difficult to realize in a real world.

Techniques of generating an image of an object in a space viewed from a predetermined viewpoint are taught in Japanese Patent Application Laid-Open No. 11-259687 and Japanese Patent Application Laid-Open No. 11-306383. International Application No. 2005-506613, published as US 2003067440, details one example of a device which acts on a touch sense.

### SUMMARY OF THE INVENTION

In such a system, an object composing a virtual world is represented by a two-dimensional image obtained by projecting three-dimensional shapes. Viewing the two-dimensional image, a user feels as if the user is seeing three-dimensional shapes and then recognizes three-dimensional objects. To experience a virtual world, therefore, it is premised that a user can sense a two-dimensional image by a visual sense, and feel three-dimensional shapes. This makes it difficult for a user, such as a visually handicapped person, to use this system without using a visual sense.

Accordingly, it is an object of the present invention to provide a system, method and program which can overcome the foregoing problem. The object is achieved by combinations of the features described in independent claims in the appended claims. Dependent claims define further advantageous specific examples of the present invention.

To overcome the problem, according to a first aspect of the present invention, there is provided a system that supports recognition of an object drawn in an image, comprising a memory device that stores, in association with each of a plurality of areas obtained by dividing an input image, a feature amount of an object drawn in the area; a selection section that selects a range of the input image to be recognized by a user based on an instruction therefrom; a calculation section that reads the feature amount corresponding to each area contained in the selected range from the memory device, and calculates an index value based on each read feature amount; and a control section that controls a device which acts on an acoustic sense or a touch sense based on the calculated index value. There are also provided a method and a program which support recognition of an image using the system.

The summary of the present invention does not recite all the necessary features of the invention, and sub combinations of those features may also encompass the invention.

### BRIEF DESCRIPTION OF THE DRAWINGS

FIG. 1 shows the general configuration of the computer system 10 according to the embodiment.

FIG. 2A shows a display example of a screen provided by the virtual world browser 12 according to the embodiment.

FIG. 2B is a conceptual diagram of a process of rendering an image displayed on the virtual world browser 12 according to the embodiment.

FIG. 3 shows the structure of data to be stored in the memory device 104 according to the embodiment.

FIG. 4 shows that portion of an image to be displayed on the virtual world browser 12 which is used for explaining the input image 300A and the Z buffer image 300B.

FIG. 5 shows the data structure of the input image 300A according to the embodiment.

FIG. 6 shows the data structure of the Z buffer image 300B according to the embodiment.

FIG. 7 shows the functional configurations of the support system 15 and the input/output interface 108 according to the embodiment.

FIG. 8 shows the flow of processes by which the client computer 100 according to the embodiment controls the voice output device 740 based on an image in a range designated by the user.

FIG. 9A shows the first example of a range to be recognized by the user in an image displayed on the virtual world browser 12 according to the embodiment.

FIG. 9B is a conceptual diagram of the user's view extent corresponding to the range shown in FIG. 9A.

FIG. 10A shows the second example of a range to be recognized by the user in an image displayed on the virtual world browser 12 according to the embodiment.

FIG. 10B is a conceptual diagram of the user's view extent of corresponding to the range shown in FIG. 10A.

FIG. 11 shows a change in volume when the user's view direction is changed long the straight line X.

FIG. 12 shows one example of the hardware configuration of the client computer 100 according to the embodiment.

### DETAILED DESCRIPTION OF THE INVENTION

The present invention will be described below by way of examples. However, an embodiment and modifications thereof described below do not limit the scope of the invention recited in the appended claims.

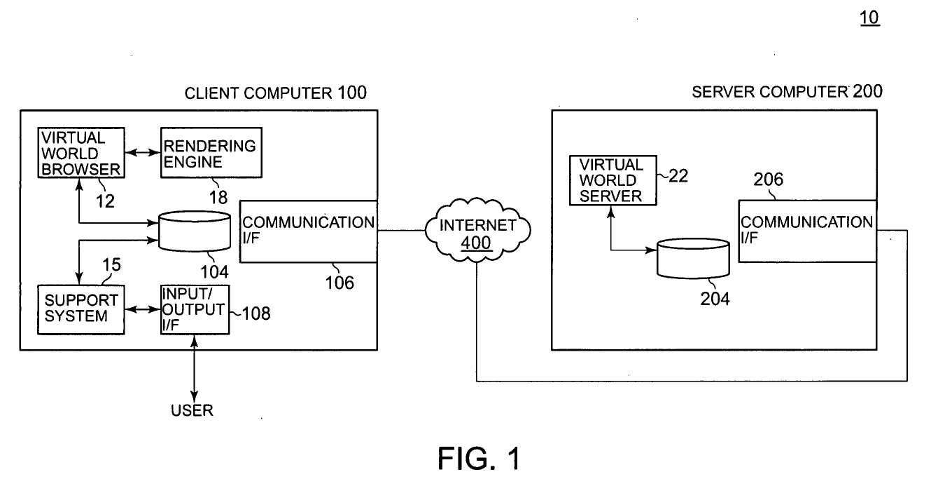

FIG. 1 shows the general configuration of a computer system 10 according to the embodiment. The computer system 10 has a client computer 100 and a server computer 200. The server computer 200 has a memory device 204, such as a hard disk drive, and a communication interface 206, such as a network interface card, as main hardware. The server computer 200 executes a program stored in the memory device 204 to serve as a virtual world server 22. The memory device 204 stores data indicating three-dimensional shapes, such as objects present in a virtual world, (e.g., data called 3D solid model). The virtual world server 22 transmits various kinds of information including such data to the client computer 100 in response to a request received from the client computer 100.

The client computer 100 has a memory device 104, such as a hard disk drive, a communication interface 106, such as a network interface card, and an input/output interface 108, such as a speaker, as main hardware. The client computer 100 executes a program stored in the memory device 104 to serve as a virtual world browser 12, a support system 15 and a rendering engine 18.

The virtual world browser 12 acquires data indicating a three-dimensional shape from the server computer 200 connected to, for example, an Internet 400. The data acquisition is achieved by cooperation of a hardware operating system for the communication interface 106 or the like, and device drivers. The rendering engine 18 generates a two-dimensional image by rendering three-dimensional shapes indicted by the acquired data, and provides the virtual world browser 12 with the two-dimensional image. The virtual world browser 12 presents the provided image to a user. When the image indicates a virtual world, the rendered image represents a field of view of an avatar (the avatar being a user's “representative” in the virtual world).

For example, the rendering engine 18 determines viewpoint coordinates and a view direction based on data input as the position and direction of an avatar, and renders a three-dimensional shape acquired from the server computer 200 to a two-dimensional plane. The viewpoint coordinates and the view direction may be input from a probe device mounted on the user as well as from a device, such as a keyboard or a pointing device. A GPS device installed on the probe device outputs real positional information of the user to the rendering engine 18. The rendering engine 18 calculates viewpoint coordinates based on the positional information and then performs rendering. This enables the user to feel as if the user were moving in the virtual world.

The support system 15 supports recognition of an object drawn in an image generated in the above manner. For example, the support system 15 controls the input/output interface 108 which acts on a sense other than a visual sense, based on an image in the object-drawn image which lies in a range selected by the user. As a result, the user can sense the position, size, color, depth and various attributes of an object drawn in an image, or any combination thereof with a sense other than the visual sense.

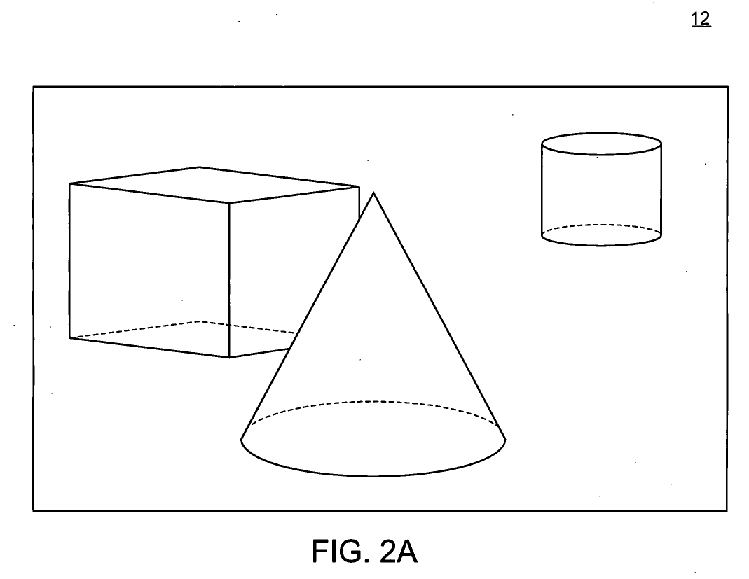

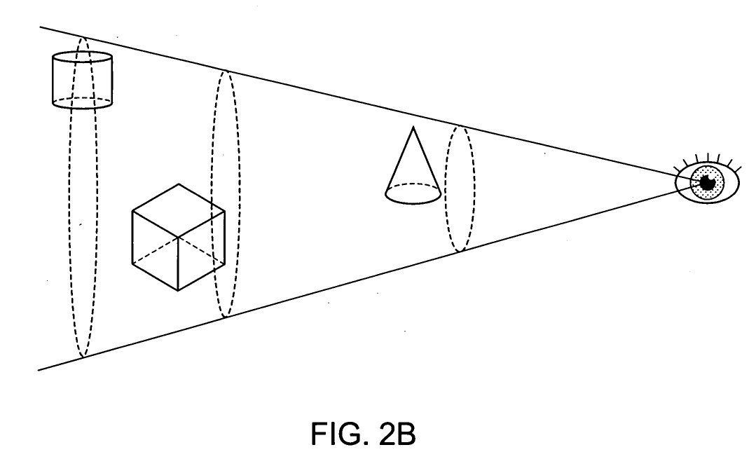

FIG. 2A shows a display example of a screen provided by the virtual world browser 12 according to the embodiment. FIG. 2B is a conceptual diagram of a process of rendering an image displayed on the virtual world browser 12 according to the embodiment. In the display example, three objects, namely a cone, a square prism and a cylinder, are drawn. Each of the objects is drawn as a two-dimensional image obtained by rendering a three-dimensional shape. The depth of the three-dimensional shape is reflected on the drawing. For example, in a virtual three-dimensional space, as shown in FIG. 2B, the square prism is located farther from the viewpoint in the rendering than the cone. In FIG. 2A, therefore, the square prism is drawn to be hidden in the shadow of the cone.

Accordingly, the user senses the depth by recognizing those two-dimensional images with the visual sense, and feels as if the user were viewing a three-dimensional shape. This allows the user to virtually experience, for example, a virtual world or the like.

To clarify the description, FIG. 2A shows the individual objects by lines, and shows lines hidden in the shadow by dotted lines. Actually, the brightness and shadow that are provided by rays of light may be drawn on the top surface of each object. Further, a predetermined texture image may be adhered to the top surface of an object.

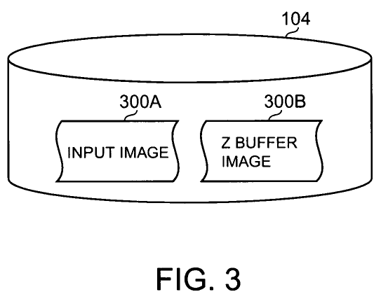

FIG. 3 shows the structure of data to be stored in the memory device 104 according to the embodiment. The memory device 104 stores an input image 300A and a Z buffer image 300B. The input image 300A indicates an image input from the server computer 200 and generated by rendering at the rendering engine 18, and is actually data in which pixel values indicating colors are arranged in the layout order of pixels.

The Z buffer image 300B is data storing a distance component of each pixel contained in the input image 300A in correspondence to that pixel. A distance component for one pixel indicates a distance from the viewpoint in rendering to a portion corresponding to the pixel in an object drawn in the input image 300A. Although the input image 300A and the Z buffer image 300B are stored in separate files in FIG. 3, they may be stored in the same file in a distinguishable manner.

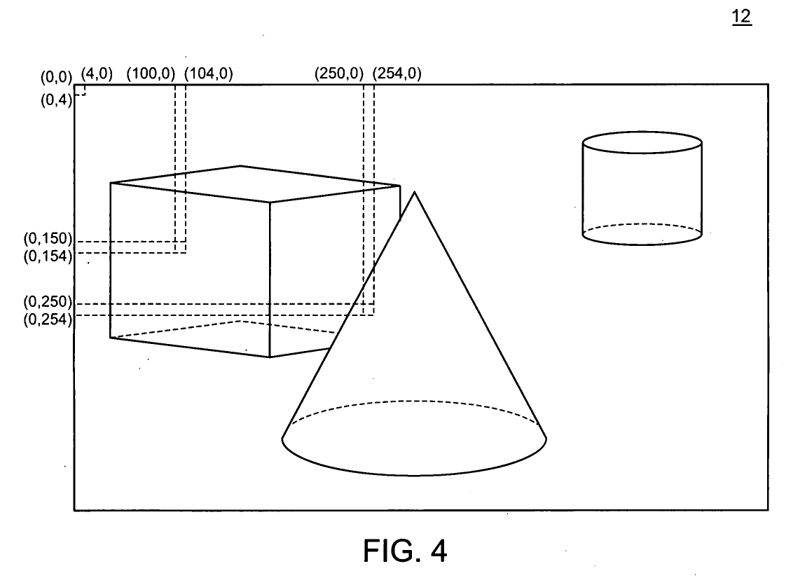

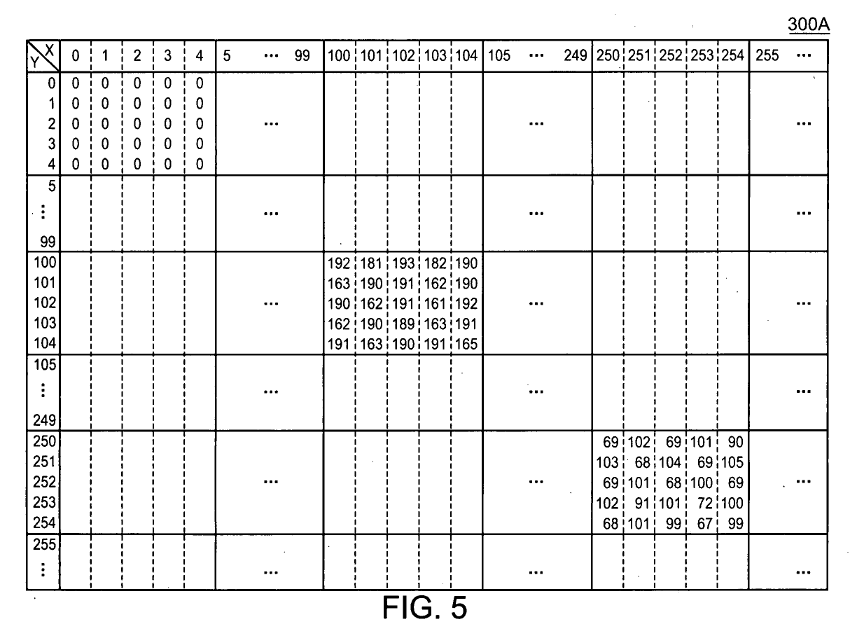

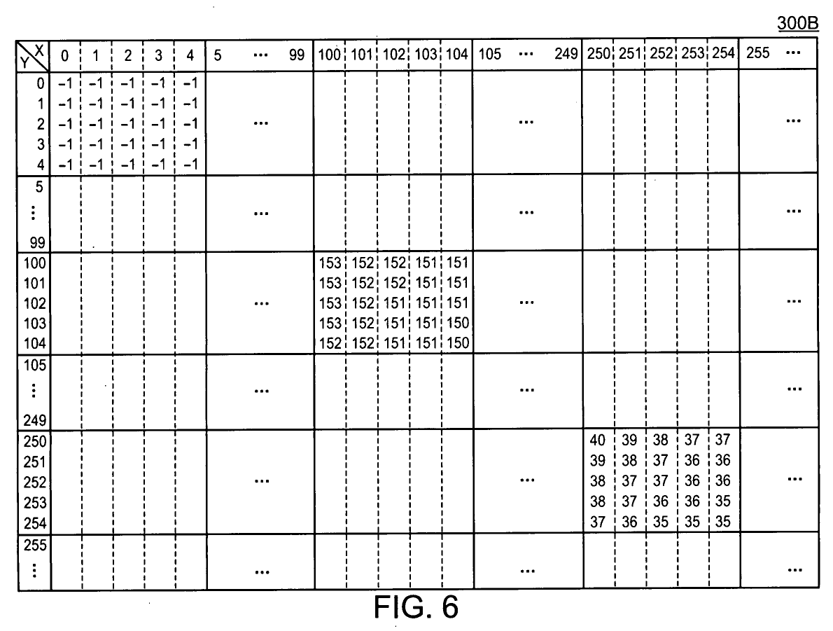

FIG. 4 shows that portion of an image to be displayed on the virtual world browser 12 which is used for explaining the input image 300A and the Z buffer image 300B. A rectangular first portion having coordinates (0, 0), coordinates (4, 0), coordinates (0, 4) and coordinates (4, 4) as vertexes is used in the descriptions of FIGS. 5 and 6.

A rectangular second portion having coordinates (100, 0), coordinates (104, 0), coordinates (0, 150) and coordinates (0, 154) as vertexes is used in the descriptions of FIGS. 5 and 6. A rectangular third portion having coordinates (250, 0), coordinates (254, 0), coordinates (0, 250) and coordinates (0, 254) as vertexes is used in the descriptions of FIGS. 5 and 6.

FIG. 5 shows the data structure of the input image 300A according to the embodiment. The input image 300A indicates data in which pixel values indicating colors are arranged in the layout order of pixels. For any pixel in the first portion, for example, the input image 300A contains a value “0” as a pixel value. The value “0” indicates that none of color elements red (R), green (G) and blue (B) is included, i.e., the color is black. Referring to FIG. 4, actually, no object is drawn in this portion.

As another example, for each pixel in the second portion, the input image 300A contains values from 160 to 200 or so. Those values indicate the intensity of one color element in a case where the color element is evaluated in 256 levels from 0 to 255. In the example of FIG. 5, therefore, the values indicate slightly different colors. Referring to FIG. 4, a rendered square prism is drawn in this portion. Gradation may be effected on the top surface of the square prism based on the relationship between a light source and the top surface, and the values indicate a part of the gradation.

As a further example, for each pixel in the third portion, the input image 300A contains values from 65 to 105 or so. Those values indicate slightly different colors. The colors differ from those of the second portion. Referring to FIG. 4, a rendered cone is drawn in this portion. Gradation may be effected on the top surface of the square prism based on the relationship between a light source and the top surface, and the values indicate a part of the gradation.

FIG. 6 shows the data structure of the Z buffer image 300B according to the embodiment. The Z buffer image 300B is data in which distance components of individual pixels are arranged in the layout pattern of the pixels. A distance component for one pixel is one example of the feature amount according to the present invention, and indicates a distance from the viewpoint in rendering to a portion corresponding to the pixel in an object drawn in the input image 300A. The example of FIG. 6 shows that the greater the value of the distance component is, the longer the distance. Because a Z buffer is generated as a side effect in the process of executing Ray-Tracing, the Z buffer need not be created newly for the embodiment.

For example, for any pixel in the first portion, the Z buffer image 300B contains a value “−1” as a distance component. The value “−1” indicates, for example, an infinite distance, and shows a value greater than any other value. Referring to FIG. 4, actually, the first portion indicates a background portion where no object is drawn.

As another example, for any pixel in the second portion, the Z buffer image 300B contains values of “150” or so. Those values indicate slightly different distances. Referring to FIG. 4, a rendered square prism is drawn in the second portion. The top surface of the square prism in this portion is inclined frontward in the rightward direction. Therefore, the distance component of each pixel corresponding to the second portion becomes smaller as the coordinate value of the X coordinate becomes larger, and does not change so much with respect to a change in the coordinate value of the Y coordinate.

As a further example, for any pixel in the third portion, the Z buffer image 300B contains values from a value “30” to “value “40” or so. Those values indicate slightly different distances. Referring to FIG. 4, a rendered cone is drawn in the third portion. The top surface of the cone in this portion is inclined frontward in the rightward direction and the downward direction. Therefore, the distance component of each pixel corresponding to the third portion becomes smaller as the coordinate value of the X coordinate becomes larger, and as the coordinate value of the Y coordinate becomes larger.

In the foregoing descriptions of FIGS. 5 and 6, a pixel value and a distance component for each pixel are illustrated as examples of the image features according to the present invention. Instead, the image features may be managed and stored for each area containing a predetermined number of pixels. For example, the Z buffer image 300B may be data storing a distance component for each area of 2×2 pixels, or data storing a distance component for each area of 4×4 pixels. It is apparent that the details of the image features do not matter as long as the index of image features is stored in association with each of a plurality of areas obtained by segmenting the input image 300A.

As another example, the feature amount is not limited to a distance component and a pixel value. For example, the feature amount may indicate the attribute value of an object. The scenario of a virtual world, for example, may include a case where each object is associated with an attribute indicating the owner or manager of that object. The memory device 104 may store such attributes of objects drawn in a plurality of areas obtained by segmenting the input image 300A, in association with the areas. It is to be assumed in the following description that the memory device 104 stores the input image 300A and the Z buffer image 300B.

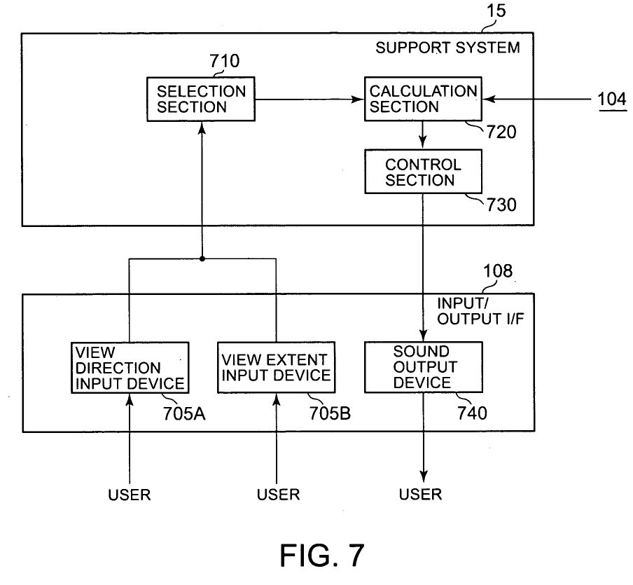

FIG. 7 shows the functional configurations of the support system 15 and the input/output interface 108 according to the embodiment. The support system 15 has a selection section 710, a calculation section 720 and a control section 730. The input/output interface 108 has a view direction input device 705A, a view extent input device 705B and a voice output device 740. The selection section 710 selects a range in the input image 300A to be recognized by the user based on an instruction from the user.

Specifically, the selection section 710 accepts an input in the virtual view direction from the user using the view direction input device 705A. The virtual view direction is coordinates of, for example, a point in the display area of the input image 300A. Then, the selection section 710 accepts an input of the virtual view extent of the user using the view extent input device 705B. The virtual view extent is the size of a range to be recognized with the accepted coordinates taken as a reference. Then, the selection section 710 selects the accepted size of the range with the accepted coordinates taken as a reference.

As one example, the selection section 710 accepts an input of center coordinates in a circular range using view direction input device 705A. The selection section 710 accepts an input of the radius or diameter of the circular range using the view extent input device 705B. Then, the selection section 710 selects the range with the accepted radius or diameter about the center coordinates taken as the center as the range to be recognized by the user.

As another example, the selection section 710 accepts an input of the coordinates of one vertex of a rectangular range using view direction input device 705A. The selection section 710 accepts an input of the length of one side of the rectangular range using the view extent input device 705B. Then, the selection section 710 selects the range of a square which has the accepted length as the length of one side as the range to be recognized by the user.

The view direction input device 705A is realized by a pointing device, such as a touch panel, a mouse or a track ball. Note that the view direction input device 705A is not limited to those devices as long as it is a two-degree-of-freedom device which can accept an input of coordinate values on a plane. The view extent input device 705B is realized by a device, such as a slider or a wheel. Note that the view extent input device 705B is not limited to those devices as long as it is a one-degree-of-freedom device which can accept an input of a value indicating the size of the range. The one-degree-of-freedom device can allow the user to change the size of the range as if to change the focus range of a camera.

In general, if the size of the range is made adjustable with a solid angle (one degree of freedom), the relationship between a directional vector r and an area vector S is expressed by the following equation 1.

[Eq. 1]

$$Ω = \int {\int }_{S} \frac{r \cdot d S}{{r}^{3}} \qquad equation 1$$

The calculation section 720 reads from the memory device 104 the feature amount corresponding to each area (e.g., pixel) contained in the selected range. Then, the calculation section 720 calculates an index value based on each feature amount read. For example, the calculation section 720 may read a distance component corresponding to each pixel from the Z buffer image 300B in the memory device 104, and may calculate an index value based on the sum or the average value of the read distance components.

The control section 730 controls the voice output device 740 which acts on the acoustic sense of the user based on the calculated index value. For example, the control section 730 makes the loudness of a sound from the voice output device 740 greater when the average value of the distances indicated by the index value is smaller as compared with a case where the average value of the distances indicated by the index value is larger.

When the size of the range input by the view extent input device 705B is fixed, the control section 730 has only to control the voice output device 740 based on the sum of the distances. For example, the control section 730 makes the loudness of a sound from the voice output device 740 greater when the average value of the distances indicated by the index value is smaller as compared with a case where the average value of the distances indicated by the index value is larger.

While the voice output device 740 is realized by a device, such as a speaker or a headphone, in the embodiment, the device which acts on the user is not limited to those devices. For example, the input/output interface 108 may have a device like a vibrator which causes vibration instead of the voice output device 740. The device that is to be controlled by the control section 730 is not limited to the voice output device 740, as long as it acts on the user's acoustic sense or touch sense. In this case, the control section 730 controls the reaction by such a device. Specifically, the types of the device reaction include the level of a sound, the height of the frequency of a sound, the sound pressure of a sound, the amplitude of vibration, and the level of the frequency of vibration (number of vibrations).

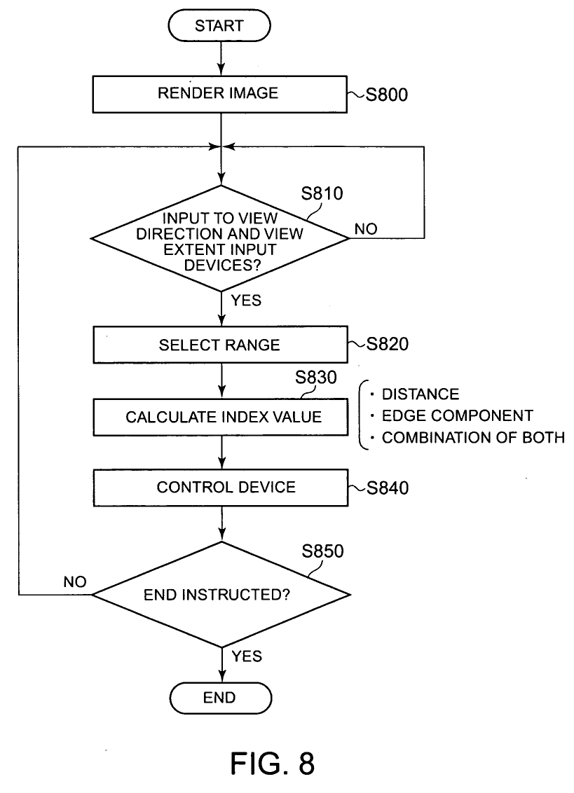

FIG. 8 shows the flow of processes by which the client computer 100 according to the embodiment controls the voice output device 740 based on an image in a range designated by the user. First, the rendering engine 18 generates an image by rendering a three-dimensional shape (S800). The generated image is stored in the memory device 104 as the input image 300A. In addition, the rendering engine 18 generates, for each pixel of the input image 300A, a distance from a viewpoint in the rendering to that portion in the three-dimensional shape which corresponds to the pixel, and stores the distance in the memory device 104. Data in which the distance components are arranged in the layout order of the pixels is the Z buffer image 300B.

Next, the client computer 100 stands by until the view direction input device 705A or the view extent input device 705B accepts an input (S810: NO). When the view direction input device 705A or the view extent input device 705B accepts an input (S810: YES), the selection section 710 selects a range in the input image 300A to be recognized by the user based on the accepted input (S820). Alternatively, the selection section 710 changes the range already selected, based on the input.

Next, every time the range to be selected is changed, the calculation section 720 reads the feature amount corresponding to each pixel contained in the selected range from the memory device 104, and calculates an index value based on each read feature amount (S830). This processing may take a variety of variations discussed below.

### (1) Distance-Component Based Mode

The calculation section 720 reads a distance component corresponding to each pixel contained in the selected range from the Z buffer image 300B in the memory device 104, and calculates an index value based on each read distance component. Let Z_{i,j} be a distance represented by a distance component for a pixel having coordinates (i, j). Also let S be the selected range. In this case, an index value t to be calculated is expressed by, for example, the following equation 2.

[Eq. 2]

$$t = \frac{1}{S} {\sum }_{i , j ∈ S} \frac{1}{{Z}_{i , j}^{2}} \qquad equation 2$$

The index value t in this case becomes a value which is inversely proportional to a square of the distance to an object corresponding to each pixel contained in the range S, and is inversely proportional to the area of the range S. That is, when an object positioned close to a viewpoint occupies that range S, t becomes a larger value. When the inversely reciprocal portion of the square of the distance is generalized in f(Zi,j), the index value t is expressed as follows.

[Eq. 3]

$$t = \frac{1}{S} {\sum }_{i , j ∈ S} f ( {Z}_{i , j} ) \qquad equation 3$$

### (2) Edge-Component Based Mode

The calculation section 720 reads a pixel value corresponding to each pixel contained in the selected range from the input image 300A in the memory device 104, and calculates an index value indicating an edge component contained in an image in the selected range based on each read pixel value. Specifically, first, the calculation section 720 calculates a luminance component based on an RGB element of the pixel value.

Given that R_{i,j} is a red component at coordinates (i, j), G_{i,j} is a green component at the coordinates (i, j) and B_{i,j} is a blue component at the coordinates (i, j), a luminance component L_{i,j} of the pixel at the coordinates (i, j) is expressed by the following equation 4.

[Eq. 4]

L_{i,j}=0.29891×R_{i,j}+0.58661×G_{i,j}+0.11448×B_{i,j} equation 4

Next, the calculation section 720 calculates edge components in the vertical direction and horizontal direction by applying, for example, a Sobel operator to a luminance image in which the luminance components are arranged in the layout order of the pixels. Given that E^{V}_{i,j} is a vertical edge component and E^{H}_{i,j} is a horizontal edge component, the calculation is expressed by the following equation 5.

[Eq. 5]

E_{i,j}^{V}=−L_{i-1,j-1}−2L_{i,j-1}−L_{i+1,j-1}+L_{i-1,j+1}+2L_{i,j+1}+L_{i+1,j+1},

E_{i,j}^{H}=−L_{i-1,j-1}−2L_{i-1,j}−L_{i-1,j+1}+L_{i-1,j-1}+2L_{i-1,j}+L_{i+1,j+1} equation 5

Then, the calculation section 720 calculates the sum of the edge components from the following equation 6.

[Eq. 6]

E_{i,j}=\sqrt{(E_{i,j}^{V})²+(E_{i,j}^{H})²} equation 6

Of the edge components E_{i,j} calculated this way, the sum or average of the edge components for the selected range S may be the index value t. The calculation on the edge components can be realized by using various image processing schemes, such as a Laplacian filter or Prewitt filter. Therefore, the scheme of calculating an edge component in the embodiment is not limited to those schemes given by the equations 4 to 6.

In place of the foregoing example, the index value t may be calculated based on the combination of an edge component and a distance component as described below.

### (3) Combination of Distance Component and Edge Component

For example, the calculation section 720 may divide the edge component of each pixel contained in the range S by the square of the distance for that pixel, and sum up the calculated values for the individual pixels contained in the range S as the index value t, as given by an equation 7 below. A distance Z′_{i,j} in the equation indicates the largest one of the distances of 3×3 pixels about the coordinates (i, j) taken as the center.

[Eq. 7]

$$t = {\sum }_{i , j ∈ S} \frac{{E}_{i , j}}{{Z}_{i , j}^{′2}} \qquad equation 7$$

Accordingly, it is possible to calculate the index value t which becomes larger as an edge component contained in the range S gets larger, and calculate the index value t which becomes larger as a distance component contained in the range S gets larger.

### (4) Edge Component of Z Buffer Image

There are further variations of the combination of a distance component and an edge component. For example, for a Z buffer image in which values indicating distances corresponding to respective pixels contained in the range S are arranged in the layout order of the pixels, the calculation section 720 may calculate the edge component of the Z buffer image as an index value. This means that a greater index value is calculated for a range which contains a larger number of portions having large distance changes.

Further, the calculation section 720 may calculate an index value indicating both the edge component of the Z buffer image 300B in the range S and the edge component of an image in the range S. The index value t thus calculated is expressed by, for example, an equation 8 below.

[Eq. 8]

$$t = {\sum }_{i , j ∈ S} \frac{α {E}_{i , j} + ( 1 - α ) {F}_{i , j}}{{Z}_{i , j}^{′2}} \qquad equation 8$$

In the equation, F_{i,j} indicates an edge component at the coordinates (i, j) of the Z buffer image 300B. α indicates a blend ratio of those two edge components, which takes a real number from 0 to 1. The combination of a discontinuous component acquired from the Z buffer with the edge component of the input image 300A can make the index value t larger for a range containing the boundary between an object and the background (e.g., the contour or ridge of an object).

### (5) Other

The calculation section 720 may calculate a plurality of index values, not just one of various index values mentioned above. As will be described later, the control section 730 uses the calculated index values to control the reaction by the sound output device 740.

Next, the control section 730 will be described. The control section 730 controls the sound output device 740 based on the calculated index value (S840). In the case (1), for example, the control section 730 makes the reaction by the sound output device 740 greater when the average value of the distances indicated by the index value is smaller as compared with a case where the average value of the distances indicated by the index value is larger.

In the case (2), the control section 730 makes the reaction by the sound output device 740 greater when the edge component indicated by the index value is larger as compared with a case where the edge component indicated by the index value is smaller. In the case (3), the combination of the processes in those two cases is taken.

In the case (4), the device reaction is influenced by the combination of the edge component of the input image 300A and the edge component of the Z buffer image 300B. If the edge component for the range S of the input image 300A is constant, the control section 730 makes the reaction by the sound output device 740 greater when the edge component indicated by the index value is larger for the range S of the Z buffer image 300B as compared with a case where the edge component indicated by the index value is smaller for the range S of the Z buffer image 300B.

If the edge component for the range S of the Z buffer image 300B is constant, on the other hand, the control section 730 makes the reaction by the sound output device 740 greater when the edge component indicated by the index value is larger for the range S of the input image 300A as compared with a case where the edge component indicated by the index value is smaller for the range S of the input image 300A.

More specifically, the control section 730 may calculate a frequency f, a sound pressure p or the intensity (amplitude) a of vibration using the index value t from the following equation 9 where c_{f}, cₚ and cₐ are predetermined constants for adjustment. The control section 730 may vibrate the sound output device 740 based on the frequency f, the sound pressure p or the amplitude a or a combination of those constants to generate a sound from the voice output device 740.

[Eq. 9]

f=10^{c}^{_{f}}^{t}[Hz],

p=cₚt[dB]

a=cₐt equation 9

Alternatively, when the calculation section 720 calculates a plurality of different index values, the control section 730 may adjust a plurality of different parameters for controlling the reaction of the sound output device 740. As one example, the control section 730 controls the loudness of a sound output from the sound output device 740 based on a first index value, and controls the pitch of the sound output from the sound output device 740 based on a second index value.

More specifically, it is desirable that the first index value should be based on the sum or average of distances corresponding to individual pixels contained in the selected range S. It is desirable that the second index value should indicate the edge component of a pixel value corresponding to each pixel contained in the selected range S.

In this case, the control section 730 makes the sound pressure of a sound output from the sound output device 740 greater when the sum or average of distances indicated by the first index value is smaller as compared with a case where the sum or average of distances indicated by the first index value is larger. Further, the control section 730 makes the pitch of a sound output from the sound output device 740 higher when the edge component indicated by the second index value is larger as compared with a case where the edge component indicated by the second index value is smaller. This control can allow the user to recognize a plurality of different components, namely a distance component and an edge component, with a single sense or an acoustic sense.

As a further example, the control section 730 may change the device reaction based on a change in index value t. For example, the control section 730 may change the device reaction based on the degree of the difference between the average value of the distance components indicated by the index value calculated by the calculation section 720 before changing the selected range and the average value of the distance components indicated by the index value calculated by the calculation section 720 after changing the selected range. This method can also make it easier to recognize the boundary between the contour of a drawn object and the background.

Next, the support system 15 determines whether an instruction to terminate the process of recognizing an image has been received or not (S850). Under a condition that such an instruction has been received (S850: YES), the support system 15 terminates the processing illustrated in FIG. 8. When such an instruction has not been received (S850: NO), the support system 15 returns the processing to step S810 to accept a view extent input and view direction input.

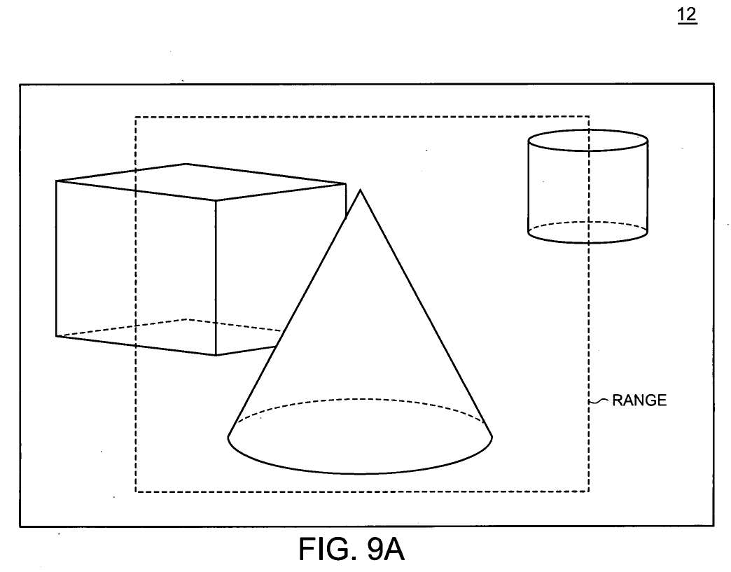

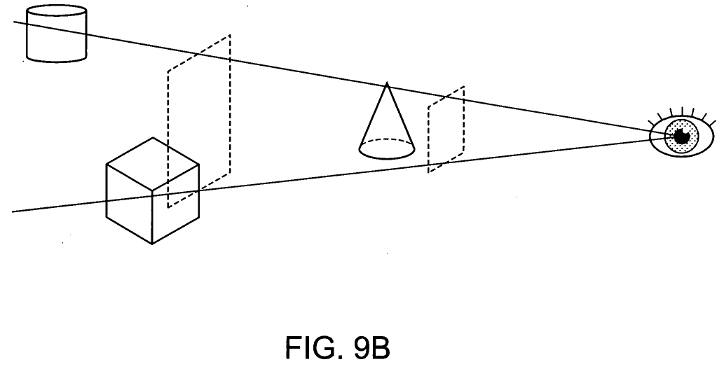

With the configuration explained above referring to FIGS. 1 to 8, the user can recognize a virtual world represented by a three-dimensional shape or the like with the acoustic sense or the touch sense. Referring to FIGS. 9 to 11, a description will be given of further specific examples where the user recognizes a three-dimensional shape in a virtual world using the embodiment.

FIG. 9A shows a first example of a range to be recognized by the user in an image displayed on the virtual world browser 12 according to the embodiment. FIG. 9B is a conceptual diagram of the user's view extent corresponding to the range shown in FIG. 9A. In this example, as shown in FIG. 9A, based on an instruction from the user, the selection section 710 selects a range which entirely contains a cone, and partially contains a square prism and a cylinder. The selected range is indicated by dotted lines. In the example, the range is represented by a rectangle. In the example, the user's virtual view extent is represented as shown in FIG. 9B, for example.

In the first example, the selected range contains various objects including the background. Therefore, the calculation section 720 calculates an index value based on the average value of distances for various portions of those objects. Then, the control section 730 causes the sound output device 740 to act with the power according to the index value.

When the view direction is changed with the view extent set wide first as in the first example, the user can grasp various objects in the display area by catching the objects with a palm as if widespread.

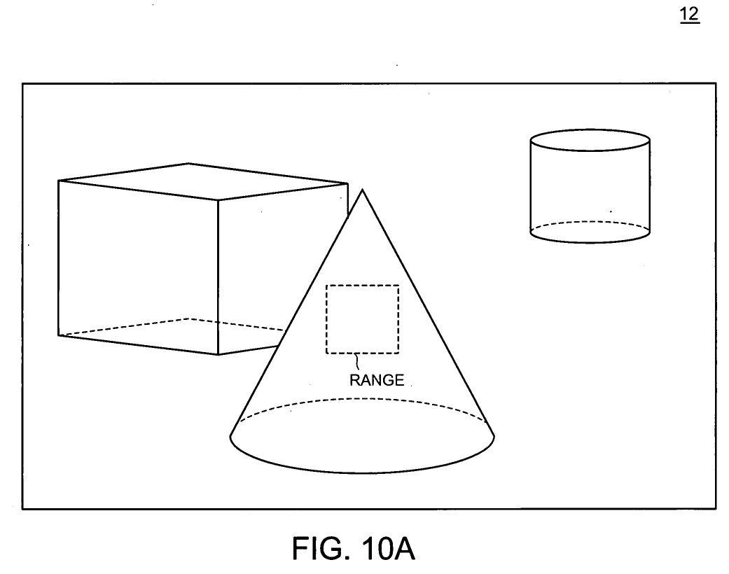

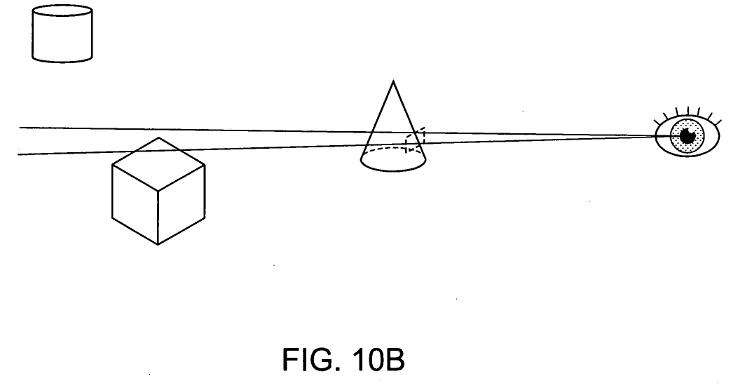

FIG. 10A shows a second example of a range to be recognized by the user in an image displayed on the virtual world browser 12 according to the embodiment. FIG. 10B is a conceptual diagram of the user's view extent corresponding to the range shown in FIG. 10A. Unlike in the first example, the selection section 710 selects a range which contains only a part of a cone. The view extent corresponding to this range includes a part of a square prism as shown in FIG. 10B. Note that because the square prism is behind the cone, it is not contained in the range selected by the selection section 710.

Therefore, the calculation section 720 calculates an index value based on a distance to the cone at the foremost position. Then, the control section 730 causes the sound output device 740 to act with the power according to the index value. In the second example, as compared with the first example, the device reaction by the control section 730 is extremely strong. The device reaction becomes gradually stronger until the view extent is made gradually narrower from the state in the first example so that the cone occupies the view extent. With the view extent becoming narrower as in the second example, the device reaction does not change so much.

If, with the view direction fixed, the view extent is made gradually narrower after the rough position of a desired object is grasped as in the second example, the approximate size of a displayed object can be grasped.

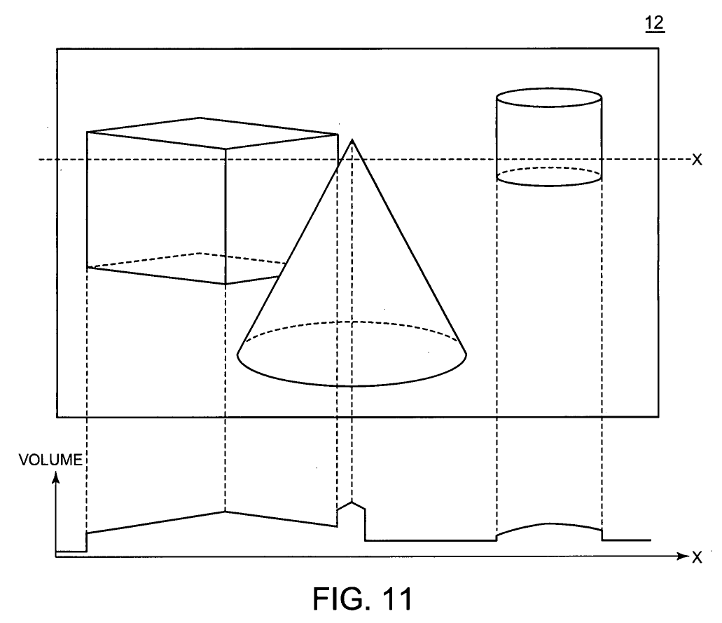

Referring to FIG. 11, a description will be given of a change in volume when the position of the range S with the size of the selected fixed is changed sequentially.

FIG. 11 shows a change in volume when the user's virtual view direction is changed along a straight line X. The example of FIG. 11 is premised on that the sound output device 740 is controlled based on a distance component. An image shown in FIG. 11 corresponds to an image shown in FIG. 2A, for example. Note that FIG. 11 includes the straight line X which crosses three objects. The straight line X represents the locus of the virtual view direction. That is, the selection section 710 moves a very small range S along the straight line X in response to an instruction sequentially given by the user.

Then, the volume changes as shown at the lower portion in FIG. 11. That is, a middle volume is generated when the view direction crosses a square prism located a little distant from the viewpoint, and the volume approaches to a peak in the vicinity of vertexes of the square prism. When the view direction reaches a cylinder closer to the viewpoint, the volume suddenly becomes larger than before. When the view direction passes the cone and approaches to the background, the volume becomes lower, and when the view direction approaches to the cylinder distant from the viewpoint, the volume increases slightly.

If the position of the range S is changed this way sequentially, the user can accurately grasp the depth as a change in volume with the acoustic sense as if a three-dimensional shape were traced with a finger. As the volume changes distinguishably at the boundary between a three-dimensional shape and the background or at a ridge line of a three-dimensional shape, the user can accurately grasp the three-dimensional shape. For example, if the view direction is changed carefully so as not to change the volume, not changed linearly, as in the example shown in FIG. 11, the locus of the view direction represents the contour.

Because the user can change the size of a range to be recognized according to the usage or the situation, as shown in FIGS. 9 to 11, the user can realize various operations, such as grasping the position and size of an object and grasping the shape or edge of an object, with an intuitive manipulation. As a result, the user can recognize a world premised on visual recognition, such as a virtual world using a three-dimensional image, with a sense, such as the acoustic sense or the touch sense, other than the visual sense.

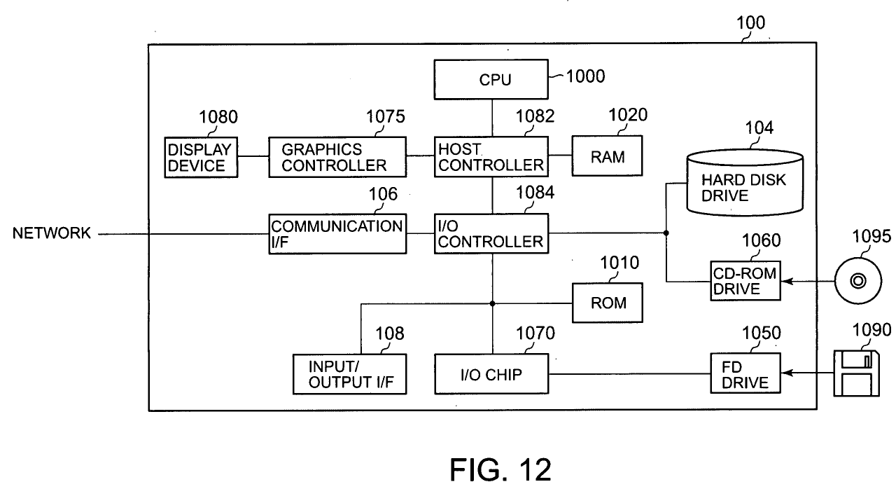

FIG. 12 shows one example of the hardware configuration of the client computer 100 according to the embodiment. The client computer 100 includes a CPU peripheral section that has a CPU 1000, a RAM 1020 and a graphics controller 1075, which are mutually connected by a host controller 1082. The client computer 100 also includes an input/output section that has a communication interface 106, a memory device (e.g., hard disk drive; hard disk drive in FIG. 12) 104, and a CD-ROM drive 1060, which are connected to the host controller 1082 by an input/output controller 1084. The client computer 100 further includes a legacy input/output section that has a ROM 1010, an input/output interface 108, a flexible disk drive 1050 and an input/output chip 1070, which are connected to the input/output controller 1084.

The host controller 1082 connects the RAM 1020 to the CPU 1000 and the graphics controller 1075, which accesses the RAM 1020 at a high transfer rate. The CPU 1000 operates to control the individual sections based on programs stored in the ROM 1010 and the RAM 1020. The graphics controller 1075 acquires image data which is generated by the CPU 1000 or the like on a frame buffer provided in the RAM 1020. Instead, the graphics controller 1075 may include a frame buffer inside to store image data generated by the CPU 1000 or the like.

The input/output controller 1084 connects the host controller 1082 to the communication interface 106, the hard disk drive 104 and the CD-ROM drive 1060, which are relatively fast input/output devices. The communication interface 106 communicates with an external device over a network. The hard disk drive 104 stores programs and data which the client computer 100 uses. The CD-ROM drive 1060 reads programs and data from a CD-ROM 1095, and provides the RAM 1020 or the hard disk drive 104 with the programs and data.

The input/output controller 1084 is connected with the ROM 1010, the input/output interface 108, and relatively slow input/output devices, such as the flexible disk drive 1050 and the input/output chip 1070. The ROM 1010 stores a boot program which is executed by the CPU 1000 when the client computer 100 is activated, and programs or the like which depend on the hardware of the client computer 100. The flexible disk drive 1050 reads programs and data from a flexible disk 1090, and provides the RAM 1020 or the hard disk drive 104 with the programs and data via the input/output chip 1070.

The input/output chip 1070 connects flexible disk 1090 to various kinds of input/output devices via, for example, a parallel port, a serial port, a keyboard port, a mouse port and so forth. The input/output interface 108 outputs a sound or causes vibration to thereby act on the acoustic sense or the touch sense. The input/output interface 108 accepts an input made from the user by the pointing device or slider.

The programs that are supplied to the client computer 100 are stored in a recording medium, such as the flexible disk 1090, the CD-ROM 1095 or an IC card, to be provided to a user. Each program is read from the recording medium via the input/output chip 1070 and/or the input/output controller 1084, and is installed on the client computer 100 to be executed. Because the operations which the programs allow the client computer 100 or the like to execute are the same as the operations of the client computer 100 which have been explained referring to FIGS. 1 to 11, their descriptions will be omitted.

The programs described above may be stored in an external storage medium. An optical recording medium, such as DVD or PD, a magneto-optical recording medium, such as MD, a tape medium, a semiconductor memory, such as an IC card, and the like can be used as storage mediums in addition to the flexible disk 1090 and the CD-ROM 1095. A storage device, such as a hard disk or RAM, provided at a server system connected to a private communication network or the Internet can be used as a recording medium to provide the client computer 100 with the programs over the network.

Although the embodiment of the present invention has been described above, the technical scope of the invention is not limited to the scope of the above-described embodiment. It should be apparent to those skilled in the art that various changes and improvements can be made to the embodiment. It is apparent from the description of the appended claims that modes of such changes or improvements are encompassed in the technical scope of the invention.

1. A system that supports recognition of an object drawn in an image, comprising:
a memory device for storing, in association with each of a plurality of areas obtained by dividing an input image, a feature amount of an object drawn in the area;
a selection section for selecting a range of the input image to be recognized by a user based on an instruction therefrom;
a calculation section for reading the feature amount corresponding to each area contained in the selected range from the memory device, and calculating an index value based on each read feature amount; and
a control section for controlling a device which acts on an acoustic sense or a touch sense based on the calculated index value.

2. The system according to claim 1, wherein
the input image includes an object obtained by rendering a three-dimensional shape,
the memory device stores, for each pixel of the input image, a distance from a viewpoint of the rendering to a portion of the three-dimensional shape corresponding to the pixel as the feature amount,
the calculation section reads the distances corresponding to the respective pixels contained in the selected range from the memory device, and calculates the index value based on a sum of the read distances, and
the control section makes reaction by the device greater when the sum of the distances indicated by the index value is smaller as compared with a case where the sum of the distances indicated by the index value is larger.

3. The system according to claim 2, wherein
the selection section accepts inputs of coordinates in a display area of the input image and a size of the range with the coordinates being a reference, and selects a range with the accepted size with the accepted coordinates being the reference,
the calculation section calculates the index value based on an average value of the distances corresponding to the respective pixels contained in the selected range, and
the control section makes reaction by the device greater when the average value of the distances indicated by the index value is smaller as compared with a case where the average value of the distances indicated by the index value is larger.

4. The system according to claim 1, wherein
the input image includes an object obtained by rendering a three-dimensional shape,
the memory device stores, for each pixel of the input image, a distance from a viewpoint of the rendering to a portion of the three-dimensional shape corresponding to the pixel as the feature amount,
the calculation section calculates, for a Z buffer image obtained by arranging values indicating the distances corresponding to the respective pixels contained in the selected range according to a layout order of the pixels, an edge component of the Z buffer image as the index value, and
the control section makes reaction by the device greater when the edge component indicated by the index value is larger as compared with a case where the edge component indicated by the index value is smaller.

5. The system according to claim 4, wherein
the memory device further stores a pixel value of each pixel of the input image as the feature amount,
the calculation section calculates the index value indicating both an edge component of the Z buffer image corresponding to the selected range, and an edge component included in an image in the selected range, further based on a pixel value corresponding to each pixel contained in the selected range, and
the control section makes reaction by the device greater when the edge component indicated by the index value is larger for the Z buffer image as compared with a case where the edge component indicated by the index value is smaller for the Z buffer image, and further makes reaction by the device greater when the edge component indicated by the index value is larger for the input image as compared with a case where the edge component indicated by the index value is smaller for the input image.

6. The system according to claim 1, wherein
the memory device stores a pixel value of each pixel of the input image as the feature amount,
the calculation section calculates the index value indicating the edge component included in an image in the selected range based on a pixel value corresponding to each pixel contained in the selected range, and
the control section makes reaction by the device greater when the edge component indicated by the index value is larger as compared with a case where the edge component indicated by the index value is smaller.

7. The system according to claim 1, wherein
the device is a device that outputs a sound, and
the control section controls a loudness of a sound output by the device.

8. The system according to claim 7, wherein
the calculation section calculates a plurality of different index values based on amounts of feature corresponding to individual areas contained in the selected range, and
the control section controls the loudness of a sound output by the device based on a calculated first index value, and controls a pitch of a sound output by the device based on a calculated second index value.

9. The system according to claim 8, wherein
the input image is generated by rendering a three-dimensional shape as the object,
the memory device stores, for each pixel of the input image, a distance from a viewpoint of the rendering to a portion of the three-dimensional shape corresponding to the pixel as the feature amount, and stores a pixel value of each pixel of the input image as the feature amount,
the calculation section reads the distances corresponding to the respective pixels contained in the selected range from the memory device, calculates the first index value based on a sum of the read distances, and calculates the second index value indicating an edge component included in the selected range based on a pixel value corresponding to each pixel contained in the selected range, and
the control section makes a sound pressure of a sound output by the device larger when the sum of the distances indicated by the first index value is smaller as compared with a case where the sum of the distances indicated by the first index value is larger, and makes the pitch of a sound output by the device higher when the edge component indicated by the second index value is larger as compared with a case where the edge component indicated by the second index value is smaller.

10. The system according to claim 1, wherein
the input image includes an object obtained by rendering a three-dimensional shape,
the memory device stores, for each pixel of the input image, a distance from a viewpoint of the rendering to a portion of the three-dimensional shape corresponding to the pixel as the feature amount,
the selection section changes the range to be selected based on an instruction from the user,
every time the range to be selected is changed, the calculation section reads the distances corresponding to the respective pixels contained in the selected range from the memory device, and calculates the index value based on a sum of the read distances, and
the control section controls reaction by the device based on a sum of the read distances indicated by the index value calculated by the calculation section before the range to be selected is changed and a sum of the distances indicated by the index value calculated by the calculation section after the range to be selected is changed.

11. A system that allows a user to experience a virtual world, comprising:
a memory device;
a rendering engine for generating an image by rendering a three-dimensional shape in a virtual world based on a position and direction of an avatar of the user, generates a distance from a viewpoint of the rendered image to a portion of the three-dimensional shape corresponding to the pixel for each pixel of the generated image, and stores the distance in the memory device;
a selection section for selecting a range of a display area of the generated image which is recognized by the user based on an instruction therefrom;
a calculation section for reading a distance corresponding to each pixel contained in the selected range from the memory device, and calculates an index value based on each read distance; and
a control section for allowing the user to recognize the virtual world by controlling a device which acts on an acoustic sense or a touch sense based on the calculated index value.

12. A computer-implemented method of supporting recognition of an object drawn in an image by using a computer having a memory device that stores, in association with each of a plurality of areas obtained by dividing an input image, an feature amount of an object drawn in the area, the method comprising the steps of:
selecting a range of the input image to be recognized by a user based on an instruction therefrom;
reading the feature amount corresponding to each area contained in the selected range from the memory device, and calculating an index value based on each read feature amount; and
controlling a device which acts on an acoustic sense or a touch sense based on the calculated index value.

13. A program product for allowing a computer having a processor to serve as a system for supporting recognition of an object drawn in an image, the computer having a memory device that stores, in association with each of a plurality of areas obtained by dividing an input image, an feature amount of an object drawn in the area, the program product executable at the processor for executing the steps of:
selecting a range of the input image to be recognized by a user based on an instruction therefrom;
reading the feature amount corresponding to each area contained in the selected range from the memory device and calculating an index value based on each read feature amount; and
controlling a device which acts on an acoustic sense or a touch sense based on the calculated index value.
